(19) United States
(12) Patent Application Publication
(10) Pub. No.: US 2025/0329384 A1
(43) Pub. Date: Oct. 23, 2025

(54) MEMORY MULTI-LEVEL PROGRAMMING METHOD, MEMORY, AND ELECTRONIC DEVICE

(71) Applicant: PEKING UNIVERSITY, Beijing (CN)

(72) Inventors: Yimao CAI, Beijing (CN); Zongwei WANG, Beijing (CN); Jingwei SUN, Beijing (CN)

(73) Assignee: PEKING UNIVERSITY, Beijing (CN)

(21) Appl. No.: 19/184,862

(22) Filed: Apr. 21, 2025

(30) Foreign Application Priority Data
Apr. 22, 2024 (CN) 202410481623.9

(51) Int. Cl. G11C 11/56; G11C 13/00

(52) U.S. Cl. CPC G11C 11/5685; G11C 13/0007; G11C 13/004; G11C 13/0069; G11C 2213/79

(57) ABSTRACT

The present disclosure relates to a multi-level programming method for a memory, including: reading a stored value of a memory cell; determining whether the stored value of the memory cell is in a reference range, and if not, applying a first adjustment signal to the memory cell to adjust the stored value of the memory cell to the reference range; determining whether the stored value of the memory cell is in a target range, and if not, applying a second adjustment signal to the memory cell to adjust the stored value of the memory cell to the target range. A minimum value of the reference range is less than or equal to a minimum value of the target range, and a maximum value of the reference range is greater than or equal to a maximum value of the target range. A single-time adjustment amplitude corresponding to the second adjustment signal is smaller than a single-time adjustment amplitude corresponding to the first adjustment signal.

### CROSS-REFERENCE TO RELATED APPLICATIONS

The present disclosure claims priority to Chinese Patent Application No. 202410481623.9, entitled “Memory Multi-Level Programming Method, Memory, and Electronic Device”, filed on Apr. 22, 2024, which is incorporated herein by reference in its entirety.

### TECHNICAL FIELD

The present disclosure relates to the field of integrated circuit technologies, and particularly, to a multi-level programming method for a memory, a memory, and an electronic device.

### BACKGROUND

With the development of communication technologies and digital technologies, in order to efficiently store, access and calculate massive data, new memories such as a resistive random access memory (RRAM), a phase change memory (PRAM), a magnetoresistive random access memory (MRAM), and a ferroelectric random access memory (FeRAM) have received extensive attention and research.

However, currently, the multi-level programming method for the memory is mostly an incremental step programming pulse (ISPP) method, which has problems of a large number of programming pulses and low programming efficiency, and is difficult to follow the rapid increase of the data storage amount.

### SUMMARY

In view of this, embodiments of the present disclosure provide a multi-level programming method for a memory, a memory, and an electronic device, which improve the multi-level programming efficiency.

In order to achieve the above object, in a first aspect, some embodiments of the present disclosure provide a multi-level programming method for a memory. The memory includes a plurality of memory cells arranged in an array, and the multi-level programming method includes the following steps:
reading a stored value of a memory cell;
determining whether the stored value of the memory cell is within a reference range, and if not, applying a first adjustment signal to the memory cell to adjust the stored value of the memory cell to the reference range; and
determining whether the stored value of the memory cell is within the target range, and if not, applying a second adjustment signal to the memory cell to adjust the stored value of the memory cell to the target range.

In the above embodiment, the minimum value of the reference range is less than or equal to the minimum value of the target range, and the maximum value of the reference range is greater than or equal to the maximum value of the target range. A single-time adjustment amplitude corresponding to the second adjustment signal is less than a single-time adjustment amplitude corresponding to the first adjustment signal.

In some embodiments of the present disclosure, before determining whether the stored value of the memory cell is within the reference range, the multi-level programming method further includes presetting the target range and the reference range and presetting control parameters of the first adjustment signal. The memory cells are correspondingly connected to bit lines, word lines, and source lines, and the control parameters of the first adjustment signal include a bit line coarse adjustment voltage, a word line coarse adjustment voltage, and a maximum number of coarse adjustments.

In some embodiments of the present disclosure, the first adjustment signal includes a set pulse control signal having a fixed pulse width and a fixed amplitude.

In some embodiments of the present disclosure, the multi-level programming method further includes the following steps:
obtaining a number of adjustments applied to the stored value of the memory cell according to the first adjustment signal;
if the number of adjustments reaches the maximum number of coarse adjustments and the stored value of the memory cell is not adjusted to the reference range, performing a step of performing memory cell switching and reading a stored value of a switched memory cell; and
if the number of adjustments does not reach the maximum number of coarse adjustments and the stored value of the memory cell has been adjusted to the reference range, performing a step of determining whether the stored value of the memory cell is within the target range.

In some embodiments of the present disclosure, before determining whether the stored value of the memory cell is within the target range, the multi-level programming method further includes presetting control parameters of the second adjustment signal. The memory cells are correspondingly connected to bit lines, word lines, and source lines, and the control parameters of the second adjustment signal include a bit line start adjustment voltage, a bit line end adjustment voltage, a bit line voltage increment step, a word line start adjustment voltage, a word line end adjustment voltage, a word line voltage increment step, a source line start adjustment voltage, a source line end adjustment voltage, a source line voltage increment step, and a maximum number of fine adjustments.

In some embodiments of the present disclosure, the second adjustment signal includes a set pulse control signal and a reset pulse control signal each having an adjustable pulse width and an adjustable amplitude. The set pulse control signal is used in a first adjustment mode, and the reset pulse control signal is used in a second adjustment mode. An enabling condition of the first adjustment mode includes that the stored value of the memory cell is less than or equal to a preset value, an enabling condition of the second adjustment mode includes that the stored value of the memory cell is greater than the preset value, and ending conditions of the first adjustment mode and the second adjustment mode include that the stored value of the memory cell is within the target range and/or a number of adjustments applied to the stored value of the memory cell according to the second adjustment signal reaches the maximum number of fine adjustments. The preset value is between the minimum value of the target range and the minimum value of the reference range.

In some embodiments of the present disclosure, the multi-level programming method further includes the following steps:
in the first adjustment mode, when the stored value of the memory cell is outside the target range, determining whether the stored value of the memory cell is less than the minimum value of the target range, and if yes, updating the set pulse control signal and adjusting the stored value of the memory cell again according to the updated set pulse control signal.

Correspondingly, updating the set pulse control signal and adjusting the stored value of the memory cell again according to the updated set pulse control signal includes the following steps:
determining whether a voltage of the bit line connected to the memory cell is less than or equal to a bit line maximum preset voltage;
if yes, determining the bit line voltage increment step according to an adjustment amount of the stored value of the memory cell based on a previous set pulse control signal, and adjusting the stored value of the memory cell again according to the bit line voltage increment step; and
if not, setting the voltage of the bit line as the bit line start adjustment voltage, determining the word line voltage increment step according to the adjustment amount of the stored value of the memory cell based on the previous set pulse control signal, and adjusting the stored value of the memory cell again according to the word line voltage increment step.

In some embodiments of the present disclosure, the multi-level programming method further includes the following steps:
in the second adjustment mode, when the stored value of the memory cell is outside the target range, determining whether the stored value of the memory cell is greater than the maximum value of the target range, and if yes, updating the reset pulse control signal, and adjusting the stored value of the memory cell again according to the updated reset pulse control signal.

Correspondingly, updating the reset pulse control signal and adjusting the stored value of the memory cell again according to the updated reset pulse control signal includes the following steps:
determining whether a voltage of the source line connected to the memory cell is less than or equal to a source line maximum preset voltage;
if yes, determining the source line voltage increment step according to an adjustment amount of the stored value of the memory cell based on a previous reset pulse control signal, and adjusting the stored value of the memory cell again according to the source line voltage increment step; and
if not, setting the voltage of the source line as the source line start adjustment voltage, determining the word line voltage increment step according to the adjustment amount of the stored value of the memory cell based on the previous reset pulse control signal, and adjusting the stored value of the memory cell again according to the word line voltage increment step.

In a second aspect, some embodiments of the present disclosure also provide a memory, including memory cells, and bit lines, word lines and source lines correspondingly connected to the memory cells. The memory further includes a read circuit and a control circuit respectively connected to the bit lines, the word lines, and the source lines. The control circuit is further connected to the read circuit. The read circuit is configured to read a stored value of a memory cell. The control circuit is configured to determine whether the stored value of the memory cell is within a reference range, apply a first adjustment signal to the memory cell to adjust the stored value of the memory cell to the reference range when the stored value of the memory cell is outside the reference range, determine whether the stored value of the memory cell is within a target range when the stored value of the memory cell is within the reference range, and apply a second adjustment signal to the memory cell to adjust the stored value of the memory cell to the target range when the stored value of the memory cell is outside the target range.

Also, a minimum value of the reference range is less than or equal to a minimum value of the target range, and a maximum value of the reference range is greater than or equal to a maximum value of the target range. A single-time adjustment amplitude corresponding to the second adjustment signal is less than a single-time adjustment amplitude corresponding to the first adjustment signal.

In a third aspect, some embodiments of the present disclosure also provide an electronic device, including a memory according to some embodiments as described above.

The details of one or more embodiments of the disclosure are set forth in the accompanying drawings and the description below. Other features, objects, and advantages of the disclosure will be apparent from the description and drawings, and from the claims.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limiting the present disclosure.

FIG. 1 is a schematic flowchart of a multi-level programming method for a memory according to some embodiments.

FIG. 2 is a schematic flowchart of another multi-level programming method for a memory according to some embodiments.

FIG. 3 is a schematic diagram of performing a first adjustment mode and a second adjustment mode according to some embodiments.

FIG. 4 is a flowchart of a method for updating a set pulse control signal and adjusting a stored value of a memory cell again according to the updated set pulse control signal according to some embodiments.

FIG. 5 is a flowchart of a method for updating a reset pulse control signal and adjusting a stored value of a memory cell again according to the updated reset pulse control signal according to some embodiments.

FIG. 6 is a schematic structural diagram of a memory according to some embodiments.

FIG. 7 is a schematic diagram of an operation of a multi-level programming method for a memory according to some embodiments.

FIG. 8 is a comparison diagram of programming efficiency between a multi-level programming method for a memory provided by embodiments of the present disclosure and an ISPP method.

### DETAILED DESCRIPTION

The embodiments of the present disclosure are described below through specific examples, and those skilled in the art can easily understand other advantages and effects of the present disclosure from the content disclosed in the specification. The present disclosure may also be implemented or applied through other different specific embodiments, and various details in the specification may also be modified or changed based on different viewpoints and applications without departing from the spirit of the present disclosure. It should be noted that the following embodiments and features in the embodiments may be combined with each other without conflict.

Having described some exemplary embodiments of the present invention for purposes of illustration, it is to be understood that the invention may be embodied in other forms not specifically shown in the drawings.

To facilitate understanding of the present disclosure, the present disclosure will be described more fully hereinafter with reference to the accompanying drawings. Preferred embodiments of the present disclosure are given in the drawings. However, the present disclosure may be implemented in many different forms and is not limited to the embodiments described herein. Rather, these embodiments are provided so that the present disclosure will be thorough and complete.

Unless defined otherwise, all technical and scientific terms used herein have the same meaning as commonly understood by one of ordinary skill in the art to which this disclosure belongs. The terms used in the specification of the present disclosure herein are for the purpose of describing specific embodiments only and are not intended to limit the present disclosure.

It will be understood that when an element or layer is referred to as being “on”, “adjacent to” or “connected to” another element or layer, it can be directly on, adjacent to, connected or coupled to the other element or layer, or intervening elements or layers may be present. It will be understood that, although the terms first, second, third, etc. may be used herein to describe various elements, components, regions, layers, doping types and/or sections, these elements, components, regions, layers, doping types and/or sections should not be limited by these terms. These terms are only used to distinguish one element, component, region, layer, doping type or part from another element, component, region, layer, doping type or part. Thus, a first element, component, region, layer, doping type or section discussed below could be termed a second element, component, region, layer or section without departing from the teachings of the present disclosure.

As used herein, the singular forms “a”, “an” and “the” may be intended to include the plural forms as well, unless the context clearly indicates otherwise. It will be further understood that the terms “compose” and/or “include” when used in this specification, specify the presence of stated features, integers, steps, operations, elements, and/or components, but do not preclude the presence or addition of one or more other features, integers, steps, operations, elements, components, and/or groups thereof. Also, as used herein, the term “and/or” includes any and all combinations of the associated listed items.

Multi-level storage, as one of the directions of attention in non-volatile memories, plays a significant role in improving storage density. Taking a resistive random access memory as an example, an implementation method of multi-level storage is to introduce an intermediate resistance state between a high resistance state and a low resistance state, so that each memory cell of the resistive random access memory can store more than two states. The basic storage principle of the resistive random access memory is that the resistance exhibited by the memory cell can be reversibly converted between a high resistance state (“0” state) and a low resistance state (“1” state) under an applied voltage or current, thereby realizing the storage of data.

However, currently, the multi-level programming method is mostly an incremental step programming pulse (ISPP) method, which has problems of a large number of programming pulses and low programming efficiency, and is difficult to follow the rapid increase of the data storage amount.

In view of this, embodiments of the present disclosure provide a multi-level programming method for a memory, a memory, and an electronic device, which improve the multi-level programming efficiency.

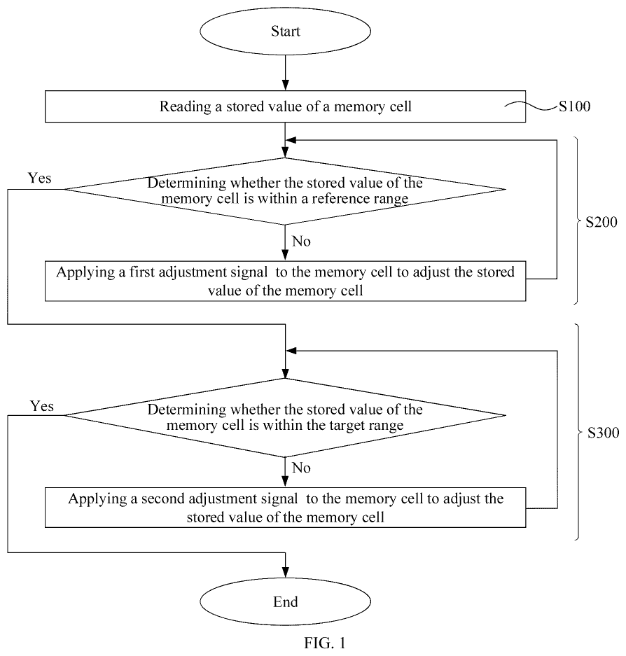

Referring to FIG. 1, embodiments of the present disclosure provide a multi-level programming method for a memory. The memory includes a plurality of memory cells arranged in an array, and the multi-level programming method includes the following steps S100 to S300.

In the step S100, a stored value of a memory cell is read.

In the step S200, whether the stored value of the memory cell is within a reference range is determined.

If not, a first adjustment signal is applied to the memory cell to adjust the stored value of the memory cell to the reference range.

If yes, the step S300 is performed.

In the step S300, whether the stored value of the memory cell is within the target range is determined.

If not, a second adjustment signal is applied to the memory cell to adjust the stored value of the memory cell to the target range.

If yes, the stored value adjustment of the memory cell is ended.

In the above embodiment, the minimum value of the reference range is less than or equal to the minimum value of the target range, and the maximum value of the reference range is greater than or equal to the maximum value of the target range. A single-time adjustment amplitude corresponding to the second adjustment signal is smaller than that of the first adjustment signal.

In the embodiments of the present disclosure, by reading the stored value of the memory cell in real time, when it is determined that the stored value of the memory cell is outside the reference range, the first adjustment signal may be applied to the memory cell to adjust the stored value of the memory cell to the reference range. Also, when the stored value of the memory cell is within the reference range and it is determined that the stored value of the memory cell is outside the target range, the second adjustment signal may be applied to the memory cell to adjust the stored value of the memory cell to the target range. In other words, the embodiments of the present disclosure can perform a single coarse adjustment of a larger amplitude in response to the first adjustment signal, and can perform a single fine adjustment of a smaller amplitude in response to the second adjustment after the stored value of the memory cell is within the reference range, thereby dynamically adjusting the stored value of the memory cell to be within the target range. Therefore, the multi-level programming method provided by the embodiments of the present disclosure can dynamically control the single-time adjustment amplitude of the stored value of the memory cell in real time to significantly shorten the multi-level programming time of the memory, thereby effectively improving the multi-level programming efficiency.

In some embodiments of the present disclosure, before the step S100, the multi-level programming method further includes initializing each memory cell of the memory.

In some embodiments of the present disclosure, before the step S200, the multi-level programming method further includes presetting the target range and the reference range, and presetting control parameters of the first adjustment signal. The memory cells are correspondingly connected to bit lines, word lines, and source lines. The control parameters of the first adjustment signal include a bit line coarse adjustment voltage, a word line coarse adjustment voltage, and a maximum number of coarse adjustments.

Exemplarily, the first adjustment signal includes a set pulse control signal (SET) having a fixed pulse width and a fixed amplitude.

Exemplarily, the step S100 includes, but is not limited to, reading an output current of the source line connected to the memory cell.

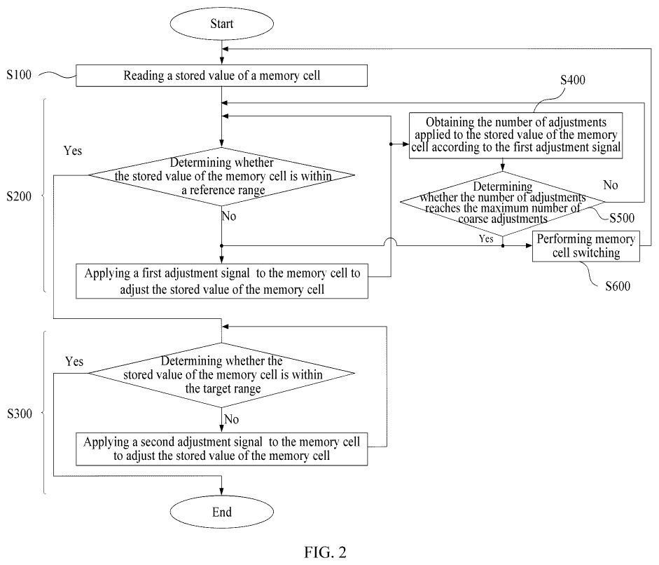

Referring to FIG. 2, in some embodiments of the present disclosure, the multi-level programming method further includes the following steps S400 to S600.

In the step S400, a number of adjustments applied to the stored value of the memory cell according to the first adjustment signal is obtained.

In the step S500, whether the number of adjustments applied to the stored value of the memory cell according to the first adjustment signal reaches a maximum number of coarse adjustments is determined.

If the number of adjustments reaches the maximum number of coarse adjustments and the stored value of the memory cell is not adjusted to the reference range, the step S600 is performed.

In the S600, memory cell switching is performed and a stored value of a switched memory cell is read.

If the number of adjustments does not reach the maximum number of coarse adjustments and the stored value of the memory cell has been adjusted to the reference range, the step of determining whether the stored value of the memory cell is within the target range in the step S300 is performed.

In some embodiments of the present disclosure, before determining whether the stored value of the memory cell is within the target range in the step S300, the multi-level programming method further includes presetting control parameters of the second adjustment signal. The memory cells are correspondingly connected to the bit lines, the word lines, and the source lines. The control parameters of the second adjustment signal include a bit line start adjustment voltage, a bit line end adjustment voltage, a bit line voltage increment step, a word line start adjustment voltage, a word line end adjustment voltage, a word line voltage increment step, a source line start adjustment voltage, a source line end adjustment voltage, a source line voltage increment step, and a maximum number of fine adjustments.

Exemplarily, the second adjustment signal includes a set pulse control signal (SET) and a reset pulse control signal (RESET) that are each adjustable in both pulse width and amplitude, where the set pulse control signal (SET) is used in the first adjustment mode, and the reset pulse control signal (RESET) is used in the second adjustment mode. The enabling condition of the first adjustment mode includes that a stored value of the memory cell is less than or equal to a preset value, and the enabling condition of the second adjustment mode includes that the stored value of the memory cell is greater than the preset value. The ending conditions of the first adjustment mode and the second adjustment mode include that the stored value of the memory cell is within the target range, and/or the number of adjustments applied to the stored value of the memory cell according to the second adjustment signal reaches the maximum number of fine adjustments. The preset value is between the minimum value of the target range and the minimum value of the reference range, that is, an open interval defined by the minimum value of the target range and the minimum value of the reference range.

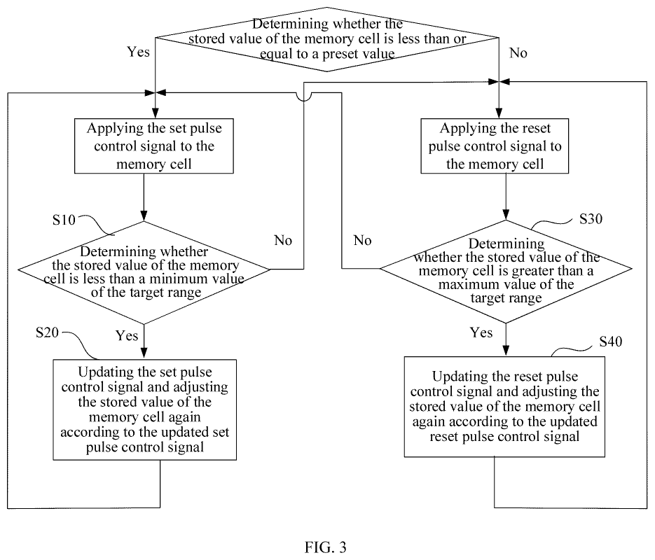

Referring to FIG. 3, in some embodiments of the present disclosure, the multi-level programming method further includes, in the first adjustment mode, when the stored value of the memory cell is outside the target range, performing steps S10 and S20.

In the step S10, whether the stored value of the memory cell is less than a minimum value of the target range is determined.

In the step S20, if yes, the set pulse control signal is updated, and the stored value of the memory cell is adjusted again according to the updated set pulse control signal.

In some exemplary embodiments, referring to FIG. 3, if it is determined that the stored value of the memory cell is greater than or equal to the minimum value of the target range, the second adjustment mode can be correspondingly performed, that is, the reset pulse control signal is applied to the memory cell.

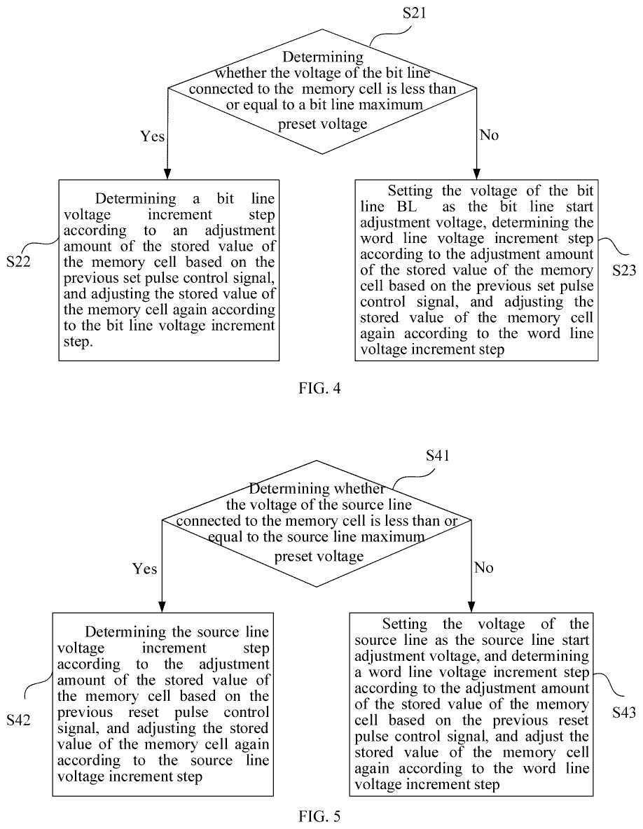

Exemplarily, referring to FIG. 4, the step S20 may include the following steps S21 to S23.

In the step S21, whether a voltage of the bit line connected to the memory cell is less than or equal to a bit line maximum preset voltage is determined.

In the step S22, if yes, the bit line voltage increment step is determined according to an adjustment amount of the stored value of the memory cell based on the previous set pulse control signal, and the stored value of the memory cell is adjusted again according to the bit line voltage increment step.

Exemplarily, the adjustment amount of the stored value of the memory cell may be represented by a relative variation of the read current.

Exemplarily, different adjustment amounts of the stored value of the memory cell may correspond to different bit line voltage increment steps, respectively.

In the step S23, if not, the voltage of the bit line is set as the bit line start adjustment voltage, a word line voltage increment step is determined according to the adjustment amount of the stored value of the memory cell based on the previous set pulse control signal, and the stored value of the memory cell is adjusted again according to the word line voltage increment step.

Still referring to FIG. 3, in some embodiments of the present disclosure, the multi-level programming method further includes, in the second adjustment mode, when the stored value of the memory cell is outside the target range, performing steps S30 and S40.

In the step S30, whether the stored value of the memory cell is greater than a maximum value of the target range is determined.

In the step S40, if yes, the reset pulse control signal is updated, and the stored value of the memory cell is adjusted again according to the updated reset pulse control signal.

In some exemplary embodiments, referring to FIG. 3, if it is determined that the stored value of the memory cell is less than or equal to the maximum value of the target range, the first adjustment mode may be performed accordingly, that is, the set pulse control signal is applied to the memory cell.

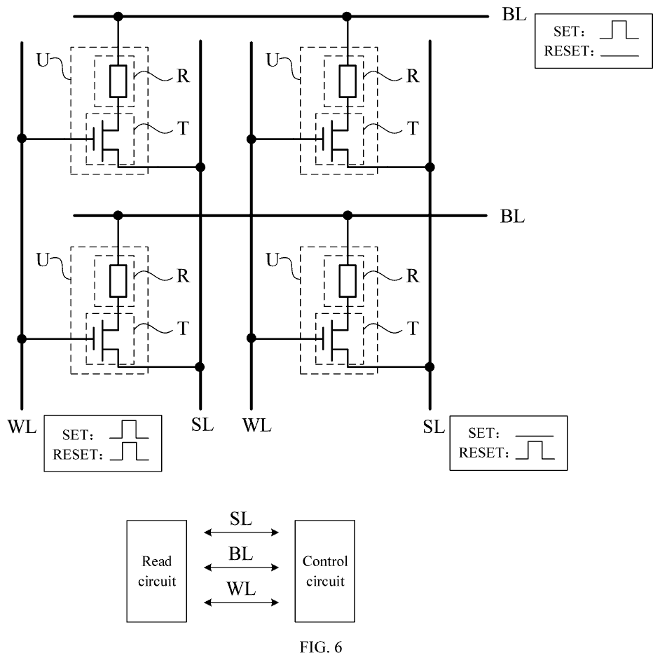

Exemplarily, referring to FIG. 5, the step S40 may include the following steps S41 to S43.

In the step S41, whether the voltage of the source line connected to the memory cell is less than or equal to the source line maximum preset voltage is determined.

In the step S42, if yes, a source line voltage increment step is determined according to the adjustment amount of the stored value of the memory cell based on the previous reset pulse control signal, and the stored value of the memory cell is adjusted again according to the source line voltage increment step.

Exemplarily, the adjustment amount of the stored value of the memory cell may be represented by a relative variation of the read current.

Exemplarily, different adjustment amounts of the stored value of the memory cell may correspond to different source line voltage increment steps, respectively.

In the step S43, if not, the voltage of the source line is set as the source line start adjustment voltage, and a word line voltage increment step is determined according to the adjustment amount of the stored value of the memory cell based on the previous reset pulse control signal, and the stored value of the memory cell is adjusted again according to the word line voltage increment step.

It should be understood that although the steps in the flowcharts involved in the above embodiments are sequentially displayed as indicated by the arrows, these steps are not necessarily performed in the order indicated by the arrows. Unless explicitly stated herein, the performing of these steps is not strictly limited, and these steps may be executed in other orders. Moreover, at least part of the steps in the flowcharts involved in the above embodiments may include multiple steps or multiple stages, these steps or stages are not necessarily performed at the same time, but may be performed at different times, and the performing order of these steps or stages is not necessarily performed sequentially, but may be performed alternately or alternately with other steps or at least part of the steps or stages in other steps.

Based on the same inventive concept, referring to FIG. 6, embodiments of the present disclosure also provide a memory, including memory cells U, and bit lines BL, word lines WL and source lines SL correspondingly connected to the memory cells U. The memory further includes a read circuit and a control circuit (not shown in FIG. 6) respectively connected to the bit lines BL, the word lines WL, and the source lines SL. The control circuit is further connected to the read circuit. The read circuit is configured to read the stored value of the memory cell U. The control circuit is configured to determine whether the stored value of the memory cell U is within a reference range, and apply a first adjustment signal to the memory cell U to adjust the stored value of the memory cell U to the reference range when the stored value of the memory cell U is outside the reference range. Also, the control circuit is configured to determine whether the stored value of the memory cell U is within a target range when the stored value of the memory cell U is within the reference range, and apply a second adjustment signal to the memory cell U to adjust the stored value of the memory cell U to the target range when the stored value of the memory cell U is outside the target range.

In addition, the minimum value of the reference range is less than or equal to a minimum value of the target range, and the maximum value of the reference range is greater than or equal to a maximum value of the target range. A single-time adjustment amplitude corresponding to the second adjustment signal is smaller than that of the first adjustment signal.

Exemplarily, the memory includes, but is not limited to, a memory that can be used to implement multi-level storage, such as a resistive memory, a phase change memory, a magnetoresistive memory, or a ferroelectric memory.

Exemplarily, the read circuit and the control circuit may each include electronic components capable of realizing their functions. The embodiments of the present disclosure do not specifically limit the composition of the read circuit and the control circuit.

Exemplarily, the stored value of the memory cell U is obtained by the read circuit reading the current of the source line connected to the memory cell U.

The solution for solving the problem provided by the above memory is similar to the solution described in the above method, so the specific limitations in one or more embodiments of the memory provided below can be understood with reference to the related limitations on the multi-level programming method above, which will not be repeated here.

In some embodiments, the control circuit is further configured to perform the multi-level programming method according to various embodiments described above.

It should be additionally noted that the process of adjusting the stored value of the memory cell U by the control circuit after applying the first adjustment signal and the second adjustment signal to the memory cell U may be implemented with reference to related description of the above-described embodiments, and details are not described herein again.

In order to more clearly illustrate the memory and the multi-level programming method for a memory provided in some of the above embodiments, the specific performing of the multi-level programming method for a memory is exemplarily described below by taking the memory being a resistive random access memory and the memory cell being a one-transistor one-resistor (1T1R) as an example in some embodiments. However, it can be understood that the multi-level programming method provided by the embodiments of the present disclosure is not only applicable to resistive memories, but also applicable to memories capable of implementing multi-level storage, such as phase change memories, magnetoresistive memories, and ferroelectric memories.

Referring to FIG. 6, the memory includes memory cells U, and bit lines BL, word lines WL, and source lines SL correspondingly connected to the memory cells U. Exemplarily, each memory cell U includes a transistor T and a resistor R. A control electrode of the transistor T, such as a gate, is connected to the word line WL, a first electrode of the transistor T, such as a source, is connected to the source line SL, a second electrode of the transistor T, such as a drain, is connected to a first end of the resistor R, and a second end of the resistor R is connected to the bit line BL.

Exemplarily, in the step S100, reading the stored value of the memory cell U may be exemplified by reading the output current I_read of the source line SL connected to the memory cell U.

Exemplarily, the first adjustment signal includes a set pulse control signal SET having a fixed pulse width and a fixed amplitude. In response to the set pulse control signal SET in the first adjustment signal, the source line SL is grounded (GND), a SET voltage is applied to the bit line BL connected to the selected memory cell U, a turn-on voltage is applied to the word line WL connected to the selected memory cell U and the transistor T is controlled to be turned on, the bit line BL connected to the unselected memory cells U is floating, and the word line WL connected to the unselected memory cells U is grounded (GND). The stored value of the memory cell is obtained by reading the current of the source line SL.

Exemplarily, the second adjustment signal includes a set pulse control signal SET and a reset pulse control signal RESET, each having an adjustable pulse width and an adjustable amplitude. In response to the set pulse control signal SET in the second adjustment signal, the source line SL is grounded (GND), a SET voltage is applied to the bit line BL connected to the selected memory cell U, a turn-on voltage is applied to the word line WL connected to the selected memory cell U and the transistor T is controlled to be turned on, the bit line BL connected to the unselected memory cells U is floating, and the word line WL connected to the unselected memory cells U is grounded GND. The stored value of the memory cell is obtained by reading the current of the source line SL. In response to the reset pulse control signal RESET in the second adjustment signal, the RESET voltage is applied to the source line SL connected to the selected memory cell U, the bit line BL connected to the selected memory cell U is grounded (GND), a turn-on voltage is applied to the word line WL connected to the selected memory cell U and the transistor T is controlled to be turned on, the bit line BL connected to the unselected memory cells U is floating, and the word line WL connected to the unselected memory cells U is grounded (GND). The stored value of the memory cell is obtained by reading the current of the source line SL.

Exemplarily, before performing step S100 in the multi-level programming method provided by the embodiments of the present disclosure, the multi-level programming method further includes initializing each memory cell of the memory. Exemplarily, the initial reset pulse control signal RESET may be applied to each memory cell of the memory, so that each memory cell U is in a high resistance state HRS.

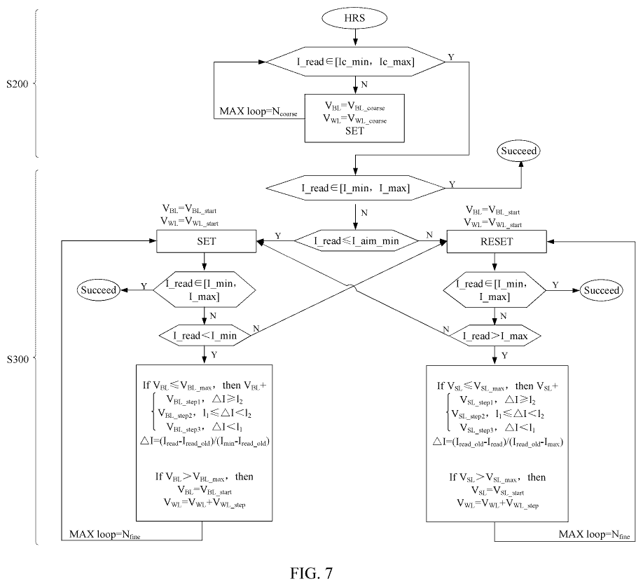

The following can be understood with reference to FIG. 7.

Before determining whether the stored value is within the reference range in the step S200, the multi-level programming method further includes presetting the target range and the reference range, and presetting the control parameters of the first adjustment signal.

The target range here is, for example, [I_min, I_max]. The reference range is, for example, [Ic_min, Ic_max]. The control parameters of the first adjustment signal SET include a bit line coarse adjustment voltage V_{BL_coarse}, a word line coarse adjustment voltage V_{WL_coarse} and a maximum number of coarse adjustments N_{coarse}.

Exemplarily, Ic_min≤I_min and Ic_max≥I_max.

During the performing of step S200, a series of first adjustment signals (i.e., set pulse control signals SET) are applied to the selected memory cell U in the high resistance state HRS. If the read current I_read of the stored value of the memory cell U has not fallen within the reference range [Ic_min, Ic_max] within the maximum number of coarse adjustments N_{coarse} (i.e., MAX loop=N_{coarse}), it is determined that the coarse adjustment fails, and the next memory cell U may be switched to and the step of reading the stored value of the switched memory cell U is performed. If the stored value of the memory cell U has been adjusted to the reference range within the maximum number of coarse adjustments N_{coarse} (i.e., MAX loop=N_{coarse}), the step S300 is performed to perform finer resistance adjustment on the memory cell U whose stored value has entered the reference range.

Similarly, before determining whether the stored value of the memory cell is within the target range in the step S300, the multi-level programming method further includes presetting control parameters of the second adjustment signal.

Here, the control parameters of the second adjustment signal include a bit line start voltage V_{BL_start}, a bit line end adjustment voltage V_{BL_end}, a bit line voltage increment step V_{BL_step}, a word line start adjustment voltage V_{WL_start}, a word line end adjustment voltage V_{WL_end}, a word line voltage increment step V_{WL_step}, a source line start adjustment voltage V_{SL_start}, a source line end adjustment voltage V_{SL_end}, a source line voltage increment step V_{SL_step} and a maximum number of fine adjustments N_{fine}.

Exemplarily, a range of the bit line voltage increment step V_{BL_step} is from 0.05V to 0.2V, for example, 0.05V, 0.1V, or 0.2V. A range of the source line voltage increment step V_{SL_step} is from 0.05V to 0.2V, for example, 0.05V, 0.1V, and 0.2V.

Based on this, the multi-level programming method may apply the set pulse control signal SET or the reset pulse control signal RESET in the second adjustment signal according to the stored value of the read memory cell U to correspondingly perform the first adjustment mode or the second adjustment mode.

Referring to FIG. 7, when it is determined that the stored value of the memory cell U is outside the target range, by determining that the stored value of the memory cell U is less than or equal to a preset value I_aim_min, the set pulse control signal SET in the second adjustment signal may be applied when I_read≤I_aim min to enable the first adjustment mode, or the reset pulse control signal RESET in the second adjustment signal may be applied when I_read>I_aim_min to enable the second adjustment mode.

Exemplarily, the preset value I_aim_min is between the minimum value I_min of the target range and the minimum value Ic_min of the reference range, that is, an open interval (Ic_min, I_min) formed by the minimum value I_min of the target range and the minimum value Ic_min of the reference range, where Ic_min<I_min.

It should be added that the first adjustment mode and the second adjustment mode may end when it is determined that the stored value of the memory cell U is within the target range (that is, I_read∈[I_min, I_max]), and/or end when it is determined that the number of adjustments applied to the stored value of the memory cell U according to the second adjustment signal reaches the maximum number of fine adjustments (that is, MAX loop=N_{fine}).

In some embodiments, still referring to FIG. 7, when the steps S10 and S20 of the first adjustment mode are performed, by determining whether the stored value of the memory cell U is less than the minimum value I_min of the target range, the set pulse control signal SET may be updated when I_read<I_min, and the stored value of the memory cell U is adjusted again according to the updated set pulse control signal SET. Also, the reset pulse control signal RESET may be applied to the memory cell U when I_read≥I_min.

It can be understood that applying the set pulse control signal SET to the memory cell U starts from applying the bit line start voltage V_{BL_start} to the bit line BL and applying the word line start voltage V_{WL_start} to the word line WL, and applying the reset pulse control signal RESET to the memory cell U starts from applying the source line start voltage V_{SL_start} to the source line SL and applying the word line start voltage V_{WL_start} to the word line WL.

Exemplarily, the step S20 of updating the set pulse control signal SET and adjusting the stored value of the memory cell U again according to the updated set pulse control signal SET may include the following steps S21 to S23.

In the step S21, it is determined whether the voltage V_{BL} of the bit line BL connected to the memory cell U is less than or equal to the bit line maximum preset voltage V_{BL_MAX}.

Optionally, the bit line maximum preset voltage V_{BL_MAX} is less than or equal to the bit line end adjustment voltage V_{BL_end}.

In the step S22, if yes (i.e., V_{BL}≤V_{BL_MAX}), the bit line voltage increment step V_{BL_step} is determined according to the adjustment amount of the stored value of the memory cell U based on the previous set pulse control signal, and the stored value of the memory cell U is adjusted again according to the bit line voltage increment step V_{BL_step}.

Optionally, the single adjustment amount of the stored value of the memory cell U may be represented by a relative variation amount ΔI of the read current. Exemplarily, different current increment levels may be set to perform different bit line voltage increment steps V_{BL_step}, respectively.

Exemplarily, when the set pulse control signal SET is applied, a formula for obtaining the relative variation ΔI of the read current corresponding to the single adjustment amount of the stored value of the memory cell U may be: ΔI=(Iread−Iread_old)/(Imin−Iread_old), where Iread is the read current corresponding to the current stored value of the memory cell U, Iread_old is the read current corresponding to the stored value of the memory cell U under the previous reset pulse control signal, and Imin is the minimum value of the target range.

Exemplarily, the current increment may have three levels. In the first level, ΔI<l₁, and the bit line voltage increasing step V_{BL_step} adopts a first step V_{BL_step1}. In the second level, l₁≤ΔI<l₂, and the bit line voltage increasing step V_{BL_step} adopts a second step V_{BL_step2}. In the third level, l₂≤ΔI, the bit line voltage increasing step V_{BL_step} adopts a third step V_{BL_step3}. Moreover, optionally, the sequentially increasing voltage between the first step V_{BL_step1}, the second step V_{BL_step2} and the third step V_{BL_step3} is 0.05V, 0.1V or 0.2V.

In the step S23, if not (i.e., V_{BL}>V_{BL_MAX}), the voltage of the bit line BL is set as the bit line start adjustment voltage V_{BL_start}, the word line voltage increment step V_{WL_step} is determined according to the adjustment amount of the stored value of the memory cell U based on the previous set pulse control signal, and the stored value of the memory cell U is adjusted again according to the word line voltage increment step V_{WL_step}.

In some embodiments, still referring to FIG. 7, when the steps S30 and S40 of the second adjustment mode are performed, by determining whether the stored value of the memory cell U is greater than the maximum value I_max of the target range, the reset pulse control signal RESET may be updated when I_read>I_max, and the stored value of the memory cell U is adjusted again according to the updated reset pulse control signal RESET. Also, the set pulse control signal SET may be applied to the memory cell U when I_read≤I_max.

Exemplarily, the step S40 of updating the reset pulse control signal RESET and adjusting the stored value of the memory cell U again according to the updated reset pulse control signal RESET may include the following steps S41 to S43.

In the step S41, it is determined whether the voltage V_{SL} of the source line SL connected to the memory cell U is less than or equal to the source line maximum preset voltage V_{SL_MAX}.

Optionally, the source line maximum preset voltage V_{SL_MAX} is less than or equal to the source line end adjustment voltage V_{SL_end}.

In the step S42, if yes (i.e., V_{SL}≤V_{SL_MAX}), the source line voltage increment step V_{SL_step} is determined according to the adjustment amount of the stored value of the memory cell U based on the previous reset pulse control signal, and the stored value of the memory cell U is adjusted again according to the source line voltage increment step V_{SL_step}.

Optionally, the single adjustment amount of the stored value of the memory cell U may be represented by a relative variation amount ΔI of the read current. Exemplarily, different current increment levels may be set to perform different source line voltage increment steps V_{SL_step}, respectively.

Exemplarily, when the reset pulse control signal RESET is applied, a formula for obtaining the relative variation ΔI of the read current corresponding to the single adjustment amount of the stored value of the memory cell U may be: ΔI=(Iread_old−Iread)/(Iread_old−Imax), where Iread_old is the read current corresponding to the stored value of the memory cell U under the previous reset pulse control signal, Iread is the read current corresponding to the current stored value of the memory cell U, and Imax is the maximum value of the target range.

Exemplarily, the current increment has three levels. In the first level, ΔI<l₁, the source line voltage increasing step V_{SL_step} adopts a first step V_{SL_step1}. In the second level, l₁≤ΔI<l₂, the source line voltage increasing step V_{SL_step} adopts a second step V_{SL_step2}. In the third level, l₂≤ΔI, the source line voltage increasing step V_{SL_step} adopts a third step V_{SL_step3}. Moreover, optionally, the sequentially increasing voltage between the first step V_{SL_step}, the second step V_{SL_step2} and the third step V_{SL_step3} is 0.05V, 0.1V or 0.2V.

In the step S43, if not (i.e., V_{SL}≥V_{BL_MAX})), the voltage of the source line SL is set as the source line start adjustment voltage V_{SL_start}, the word line voltage increment step V_{WL_step} is determined according to the adjustment amount of the stored value of the memory cell U based on the previous set pulse control signal, and the stored value of the memory cell U is adjusted again according to the word line voltage increment step V_{WL_step}.

It is worth mentioning that in the above embodiments, if the relative variation ΔI of the read current increases, the word line voltage increment step V_{WL_step} and the corresponding bit line voltage increment step V_{BL_step} or the source line voltage increment step V_{SL_step} need to increase. On the contrary, if the relative variation ΔI of the read current decreases, the word line voltage increment step V_{WL_step} and the corresponding bit line voltage increment step V_{BL_step} or source line voltage increment step V_{SL_step} need to decrease. That is, each time the set pulse control signal SET or the reset pulse control signal RESET is updated, each step setting of the word line voltage increment step V_{WL_step} and the corresponding bit line voltage increment step V_{BL_step} or the source line voltage increment step V_{SL_step} may be determined by the adjustment amount of the stored value of the memory cell U based on the previous signal.

From the above, compared with the related incremental step pulse programming (ISPP) method, the memory and the multi-level programming method thereof provided by the embodiments of the present disclosure can dynamically control the single-time adjustment amplitude of the stored value of the memory cell in real time to significantly shorten the multi-level programming time of the memory, thereby effectively improving the multi-level programming efficiency.

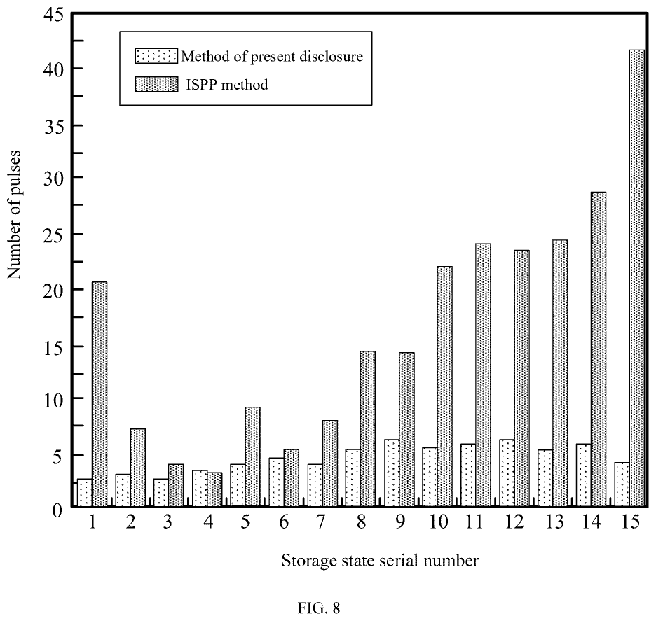

FIG. 8 shows a comparison diagram of programming efficiency between a multi-level programming method provided by embodiments of the present disclosure and an ISPP method. In FIG. 8, the horizontal axis is the storage state serial number, and the vertical axis is the number of pulses. It may be understood that one storage state may represent one stored value. With reference to the programming efficiency comparison between the method of the present disclosure and the ISPP method shown in FIG. 8, it can be seen that the method of the present disclosure can improve the multi-level programming efficiency to nearly 10 times or more of the conventional programming algorithm (i.e., the ISPP method).

Some embodiments of the present disclosure further provide an electronic device, such as a data storage device, a photocopier, a network device, a household appliance, an instrument, a mobile phone, a computer, and other devices having a data storage function. The electronic device may include a housing, a circuit board disposed in the housing, and a memory integrated on the circuit board. For the structure of the memory, reference can be made to the related descriptions in some of the above-described embodiments. The electronic device may further include other necessary elements or components, which is not limited in the embodiments of the present disclosure.

The technical features of the above embodiments may be arbitrarily combined, and in order to make the description concise, not all possible combinations of the technical features in the above embodiments are described, however, as long as there is no contradiction between the combinations of these technical features, it should be considered as the scope of the present specification.

The above embodiments only express several implementations of the present disclosure, and the description thereof is specific and detailed, but cannot be construed as limiting the patent scope of the present disclosure. It should be noted that for those of ordinary skill in the art, several variations and improvements can be made without departing from the concept of the present disclosure, which all fall within the protection scope of the present disclosure.

What is claimed is:

1. A multi-level programming method for a memory, wherein the memory comprises a plurality of memory cells arranged in an array, and the multi-level programming method comprises:
reading a stored value of a memory cell of the memory;
determining whether the stored value of the memory cell is within a reference range;
if not, applying a first adjustment signal to the memory cell to adjust the stored value of the memory cell to the reference range;
determining whether the stored value of the memory cell is within a target range; and
if not, applying a second adjustment signal to the memory cell to adjust the stored value of the memory cell to the target range; and
wherein a minimum value of the reference range is less than or equal to a minimum value of the target range, a maximum value of the reference range is greater than or equal to a maximum value of the target range, and a single-time adjustment amplitude corresponding to the second adjustment signal is less than a single-time adjustment amplitude corresponding to the first adjustment signal.

2. The multi-level programming method of claim 1, wherein before determining whether the stored value of the memory cell is within the reference range, the multi-level programming method further comprises:
presetting the target range and the reference range; and
presetting control parameters of the first adjustment signal,
wherein the memory cells are correspondingly connected to bit lines, word lines, and source lines, and the control parameters of the first adjustment signal comprise a bit line coarse adjustment voltage, a word line coarse adjustment voltage, and a maximum number of coarse adjustments.

3. The multi-level programming method of claim 2, wherein the first adjustment signal comprises a set pulse control signal having a fixed pulse width and a fixed amplitude.

4. The multi-level programming method of claim 2, further comprising:
obtaining a number of adjustments applied to the stored value of the memory cell according to the first adjustment signal;
if the number of adjustments reaches the maximum number of coarse adjustments and the stored value of the memory cell is not adjusted to the reference range, performing a step of performing memory cell switching and reading a stored value of a switched memory cell;
if the number of adjustments does not reach the maximum number of coarse adjustments and the stored value of the memory cell has been adjusted to the reference range, performing a step of determining whether the stored value of the memory cell is within the target range.

5. The multi-level programming method of claim 1, wherein before determining whether the stored value of the memory cell is within the target range, the multi-level programming method further comprises:
presetting control parameters of the second adjustment signal, and
wherein the memory cells are correspondingly connected to bit lines, word lines, and source lines, and the control parameters of the second adjustment signal comprise a bit line start adjustment voltage, a bit line end adjustment voltage, a bit line voltage increment step, a word line start adjustment voltage, a word line end adjustment voltage, a word line voltage increment step, a source line start adjustment voltage, a source line end adjustment voltage, a source line voltage increment step, and a maximum number of fine adjustments.

6. The multi-level programming method of claim 5, wherein the second adjustment signal comprises a set pulse control signal and a reset pulse control signal each having an adjustable pulse width and an adjustable amplitude;
the set pulse control signal is used in a first adjustment mode, the reset pulse control signal is used in a second adjustment mode, an enabling condition of the first adjustment mode comprises that the stored value of the memory cell is less than or equal to a preset value, an enabling condition of the second adjustment mode comprises that the stored value of the memory cell is greater than the preset value, ending conditions of the first adjustment mode and the second adjustment mode comprise that the stored value of the memory cell is within the target range, and/or a number of adjustments applied to the stored value of the memory cell according to the second adjustment signal reaches the maximum number of fine adjustments; and
the preset value is between the minimum value of the target range and the minimum value of the reference range.

7. The multi-level programming method of claim 6, further comprising:
in the first adjustment mode, when the stored value of the memory cell is outside the target range, determining whether the stored value of the memory cell is less than the minimum value of the target range; and
if yes, updating the set pulse control signal and adjusting the stored value of the memory cell again according to the updated set pulse control signal,
wherein updating the set pulse control signal and adjusting the stored value of the memory cell again according to the updated set pulse control signal comprises:
determining whether a voltage of the bit line connected to the memory cell is less than or equal to a bit line maximum preset voltage;
if yes, determining the bit line voltage increment step according to an adjustment amount of the stored value of the memory cell based on a previous set pulse control signal, and adjusting the stored value of the memory cell again according to the bit line voltage increment step; and
if not, setting the voltage of the bit line as the bit line start adjustment voltage, determining the word line voltage increment step according to the adjustment amount of the stored value of the memory cell based on the previous set pulse control signal, and adjusting the stored value of the memory cell again according to the word line voltage increment step.

8. The multi-level programming method of claim 6, further comprising:
in the second adjustment mode, when the stored value of the memory cell is outside the target range, determining whether the stored value of the memory cell is greater than the maximum value of the target range; and
if yes, updating the reset pulse control signal, and adjusting the stored value of the memory cell again according to the updated reset pulse control signal,
wherein updating the reset pulse control signal and adjusting the stored value of the memory cell again according to the updated reset pulse control signal comprises:
determining whether a voltage of the source line connected to the memory cell is less than or equal to a source line maximum preset voltage;
if yes, determining the source line voltage increment step according to an adjustment amount of the stored value of the memory cell based on a previous reset pulse control signal, and adjusting the stored value of the memory cell again according to the source line voltage increment step; and
if not, setting the voltage of the source line as the source line start adjustment voltage, determining the word line voltage increment step according to the adjustment amount of the stored value of the memory cell based on the previous reset pulse control signal, and adjusting the stored value of the memory cell again according to the word line voltage increment step.

9. A memory, comprising memory cells, and bit lines, word lines and source lines correspondingly connected to the memory cells, the memory further comprising a read circuit and a control circuit respectively connected to the bit lines, the word lines and the source lines,
wherein the read circuit is configured to read a stored value of a memory cell of the memory cells;
the control circuit is configured to determine whether the stored value of the memory cell is within a reference range, and when the stored value of the memory cell is outside the reference range, apply a first adjustment signal to the memory cell to adjust the stored value of the memory cell to the reference range, and when the stored value of the memory cell is within the reference range, determine whether the stored value of the memory cell is within a target range and when the stored value of the memory cell is outside the target range and apply a second adjustment signal to the memory cell to adjust the stored value of the memory cell to the target range; and
a minimum value of the reference range is less than or equal to a minimum value of the target range, a maximum value of the reference range is greater than or equal to a maximum value of the target range, and a single-time adjustment amplitude corresponding to the second adjustment signal is less than a single-time adjustment amplitude corresponding to the first adjustment signal.

10. The memory of claim 9, wherein before determining whether the stored value is within the reference range, the control circuit is further configured to:
preset the target range and the reference range; and
preset control parameters of the first adjustment signal, and
wherein the memory cells are correspondingly connected to the bit lines, the word lines, and the source lines, and the control parameters of the first adjustment signal comprises a bit line coarse adjustment voltage, a word line coarse adjustment voltage, and a maximum number of coarse adjustments.

11. The memory of claim 10, where the first adjustment signal comprises a set pulse control signal having a fixed pulse width and a fixed amplitude.

12. The memory of claim 10, wherein the control circuit is further configured to:
obtain a number of adjustments applied to the stored value of the memory cell according to the first adjustment signal;
if the number of adjustments reaches the maximum number of coarse adjustments and the stored value of the memory cell is not adjusted to the reference range, perform a step of performing memory cell switching and reading a stored value of a switched memory cell; and
if the number of adjustments does not reach the maximum number of coarse adjustments and the stored value of the memory cell has been adjusted to the reference range, performing a step of determining whether the stored value of the memory cell is within the target range.

13. The memory of claim 9, wherein before determining whether the stored value of the memory cell is within the target range, the control circuit is further configured to:
preset control parameters of the second adjustment signal, and
wherein the memory cells are correspondingly connected to the bit lines, the word lines, and the source lines, and the control parameters of the second adjustment signal comprise a bit line start adjustment voltage, a bit line end adjustment voltage, a bit line voltage increment step, a word line start adjustment voltage, a word line end adjustment voltage, a word line voltage increment step, a source line start adjustment voltage, a source line end adjustment voltage, a source line voltage increment step, and a maximum number of fine adjustments.

14. The memory of claim 13, wherein the second adjustment signal comprises a set pulse control signal and a reset pulse control signal each having an adjustable pulse width and an adjustable amplitude;
the set pulse control signal is used in a first adjustment mode, the reset pulse control signal is used in a second adjustment mode, an enabling condition of the first adjustment mode comprises that the stored value of the memory cell is less than or equal to a preset value, an enabling condition of the second adjustment mode comprises that the stored value of the memory cell is greater than the preset value, ending conditions of the first adjustment mode and the second adjustment mode comprise that the stored value of the memory cell is within the target range, and/or a number of adjustments applied to the stored value of the memory cell according to the second adjustment signal reaches the maximum number of fine adjustments, and
the preset value is between the minimum value of the target range and the minimum value of the reference range.

15. The memory of claim 14, further comprising:
in the first adjustment mode, when the stored value of the memory cell is outside the target range, determining whether the stored value of the memory cell is less than the minimum value of the target range; and
if yes, updating the set pulse control signal and adjusting the stored value of the memory cell again according to the updated set pulse control signal,
wherein updating the set pulse control signal and adjusting the stored value of the memory cell again according to the updated set pulse control signal comprises:
determining whether a voltage of the bit line connected to the memory cell is less than or equal to a bit line maximum preset voltage;
if yes, determining the bit line voltage increment step according to an adjustment amount of the stored value of the memory cell based on a previous set pulse control signal, and adjusting the stored value of the memory cell again according to the bit line voltage increment step; and
if not, setting the voltage of the bit line as the bit line start adjustment voltage, determining the word line voltage increment step according to the adjustment amount of the stored value of the memory cell based on the previous set pulse control signal, and adjusting the stored value of the memory cell again according to the word line voltage increment step.

16. The memory of claim 14, wherein the control circuit is further configured to:
in the second adjustment mode, when the stored value of the memory cell is outside the target range, determine whether the stored value of the memory cell is greater than the maximum value of the target range; and
if yes, update the reset pulse control signal, and adjust the stored value of the memory cell again according to the updated reset pulse control signal,
wherein updating the reset pulse control signal and adjusting the stored value of the memory cell again according to the updated reset pulse control signal comprises:
determining whether a voltage of the source line connected to the memory cell is less than or equal to a source line maximum preset voltage;
if yes, determining the source line voltage increment step according to an adjustment amount of the stored value of the memory cell based on a previous reset pulse control signal, and adjusting the stored value of the memory cell again according to the source line voltage increment step; and
if not, setting the voltage of the source line as the source line start adjustment voltage, determining the word line voltage increment step according to the adjustment amount of the stored value of the memory cell based on the previous reset pulse control signal, and adjusting the stored value of the memory cell again according to the word line voltage increment step.

17. An electronic device, comprising a memory, the memory comprising memory cells, and bit lines, word lines, and source lines correspondingly connected to the memory cells, the memory further comprising a read circuit and a control circuit respectively connected to the bit lines, the word lines and the source lines, wherein the read circuit is configured to read a stored value of a memory cell of the memory cells;
the control circuit is configured to determine whether the stored value of the memory cell is within a reference range, and when the stored value of the memory cell is outside the reference range, apply a first adjustment signal to the memory cell to adjust the stored value of the memory cell to the reference range, and when the stored value of the memory cell is within the reference range, determine whether the stored value of the memory cell is within a target range and when the stored value of the memory cell is outside the target range and apply a second adjustment signal to the memory cell to adjust the stored value of the memory cell to the target range; and
a minimum value of the reference range is less than or equal to a minimum value of the target range, a maximum value of the reference range is greater than or equal to a maximum value of the target range, and a single-time adjustment amplitude corresponding to the second adjustment signal is less than a single-time adjustment amplitude corresponding to the first adjustment signal.

18. The electronic device of claim 17, wherein before determining whether the stored value is within the reference range, the control circuit is further configured to:
preset the target range and the reference range; and
preset control parameters of the first adjustment signal, and
wherein the memory cells are correspondingly connected to the bit lines, the word lines, and the source lines, and the control parameters of the first adjustment signal comprises a bit line coarse adjustment voltage, a word line coarse adjustment voltage, and a maximum number of coarse adjustments.

19. The electronic device of claim 18, wherein the first adjustment signal comprises a set pulse control signal having a fixed pulse width and a fixed amplitude.

20. The electronic device of claim 18, wherein the control circuit is further configured to:
obtain a number of adjustments applied to the stored value of the memory cell according to the first adjustment signal;
if the number of adjustments reaches the maximum number of coarse adjustments and the stored value of the memory cell is not adjusted to the reference range, perform a step of performing memory cell switching and reading a stored value of a switched memory cell; and
if the number of adjustments does not reach the maximum number of coarse adjustments and the stored value of the memory cell has been adjusted to the reference range, performing a step of determining whether the stored value of the memory cell is within the target range.
